(19) United States
(12) Patent Application Publication
(10) Pub. No.: US 2015/0112615 A1
(43) Pub. Date: Apr. 23, 2015

(54) METHOD AND APPARATUS FOR MONITORING ENERGY MANAGEMENT EFFICIENCY OF DATA CENTER

(71) Applicant: ELECTRONICS AND TELECOMMUNICATIONS RESEARCH INSTITUTE, Daejeon-city (KR)

(72) Inventors: Sangjin JEONG, Daejeon (KR); Younghwan CHOI, Daejeon (KR); Yongwoon KIM, Asan-si (KR)

(73) Assignee: ELECTRONICS AND TELECOMMUNICATIONS RESEARCH INSTITUTE, Daejeon-city (KR)

(21) Appl. No.: 14/186,119

(22) Filed: Feb. 21, 2014

(30) Foreign Application Priority Data
Oct. 17, 2013 (KR) 10-2013-0123759

(51) Int. Cl. G01R 21/00; G05B 23/00

(52) U.S. Cl. CPC G01R 21/006; G05B 23/00
USPC 702/60

(57) ABSTRACT

An apparatus and method are disclosed for monitoring energy management efficiency of a data center. The apparatus includes an input unit, an energy management efficiency non-achievement rate calculation unit, and an average calculation unit. The input unit receives upper and lower limit target values for each of energy management efficiency measurement indicators. The energy management efficiency non-achievement rate calculation unit calculates the rate of non-achievement of energy management efficiency for each of the energy management efficiency measurement indicators based on an energy management efficiency measurement indicator value currently measured for each of the energy management efficiency measurement indicators and the upper and lower limit target values. The average calculation unit receives the rates of non-achievement of energy management efficiency for the energy management efficiency measurement indicators, and calculates the average of the rates of non-achievement of energy management efficiency.

### CROSS REFERENCE TO RELATED APPLICATION

This application claims the benefit of Korean Patent Application No. 10-2013-0123759, filed on Oct. 17, 2013, which is hereby incorporated by reference in its entirety into this application.

### BACKGROUND OF THE INVENTION

1. Technical Field

The present invention relates generally to a method and apparatus for monitoring the energy management efficiency of a data center and, more particularly, to a method and apparatus that are capable of monitoring the energy management efficiency of a data center.

2. Description of the Related Art

To monitor the energy management efficiency of a data center, a method of monitoring energy management efficiency using a control chart, such as a spider web chart, is generally used.

A spider web chart is designed to indicate a plurality of measurement targets on a single chart. A spider web chart is used to monitor the state and/or efficiency of equipment in various sites, such as a data center, a power plant, and a building. In particular, in a data center, target values for the energy management efficiency measurement indicators of the data center are indicated on a spider web chart in the form of upper and lower limits, and energy management efficiency is monitored based on locations at which values currently measured for the measurement indicators are indicated on the chart. A spider web chart is a radially extending chart that generally has a plurality of axes. Values for indicators to be measured or evaluated are indicated along the axes of the spider web chart.

A conventional system for monitoring the energy management efficiency of a data center based on a spider web chart provides the function of visualizing the results of a current measurement using a graph.

However, the conventional system for monitoring the energy management efficiency of a data center based on a spider web chart is disadvantageous in that it is difficult for the operator of a data center to be immediately aware of current status because the results of measurement are not provided in the form of quantitative numeral values.

Furthermore, the conventional system for monitoring the energy management efficiency of a data center based on a spider web chart is disadvantageous in that it is difficult to indicate the trend of changes in the energy management efficiency of a data center over time. Accordingly, to effectively monitor the energy management efficiency of a data center, the above disadvantages of the conventional system for monitoring the energy management efficiency of a data center based on a spider web chart should be overcome.

As a related preceding technology, Korean Patent Application Publication No. 10-2010-0062954 discloses a method for optimizing data distribution and power consumption in a data center, in which the power consumption of the data center is optimized by selectively reducing power for data storage devices to which data having a lower active state, such as persistent data, has been moved.

The above-described invention disclosed in Korean Patent Application Publication No. 10-2010-0062954 is intended merely to optimize the power consumption of the data center by selectively reducing power for the data storage devices, and is distinguished from a method of measuring and evaluating energy management efficiency.

### SUMMARY OF THE INVENTION

Accordingly, the present invention has been made keeping in mind the above problems occurring in the conventional art, and an object of the present invention is to provide a method and apparatus that are capable of quantitatively indicating whether current energy management efficiency falls within a range of set target values by extending a conventional control chart-based energy management efficiency monitoring method using a spider web chart, thereby enabling the operator of a data center to effectively monitor energy management efficiency.

In accordance with an aspect of the present invention, there is provided a method of monitoring the energy management efficiency of a data center, including receiving, by an input unit, upper and lower limit target values for each of energy management efficiency measurement indicators; calculating, by an energy management efficiency non-achievement rate calculation unit, the rate of non-achievement of energy management efficiency for each of the energy management efficiency measurement indicators based on an energy management efficiency measurement indicator value currently measured for each of the energy management efficiency measurement indicators and the upper and lower limit target values; and receiving, by an average calculation unit, the rates of non-achievement of energy management efficiency for the energy management efficiency measurement indicators, and calculating, by the average calculation unit, the average of the rates of non-achievement of energy management efficiency (an average rate of non-achievement of the energy management efficiency of the data center).

Calculating the average may include outputting the calculated average in a numerical value form.

Calculating the average may include calculating the average using the following equation:

$$A {V}_{ef}^{N} = \frac{{\sum }_{i = 1}^{N} {( MAX ( \vert {x}_{i} - {UB}_{i} \vert , \vert {x}_{i} - L {B}_{i} \vert ) )}^{2}}{N}$$

where AVef is the average rate of non-achievement of the energy management efficiency of the data center, xi is management efficiency for the i-th energy management efficiency measurement indicator, LBi is a lower limit target value for the i-th energy management efficiency measurement indicator, UBi is an upper limit target value for the i-th energy management efficiency measurement indicator, and N is a number of energy management efficiency measurement indicators of the data center.

xi, LBi and UBi may be each equal to or larger than 0, and may be each equal to or smaller than 1.

In accordance with another aspect of the present invention, there is provided an apparatus for monitoring energy management efficiency of a data center, including an input unit configured to receive upper and lower limit target values for each of energy management efficiency measurement indicators; an energy management efficiency non-achievement rate calculation unit configured to calculate the rate of non-achievement of energy management efficiency for each of the energy management efficiency measurement indicators based on an energy management efficiency measurement indicator value currently measured for each of the energy management efficiency measurement indicators and the upper and lower limit target values; and an average calculation unit configured to receive the rates of non-achievement of energy management efficiency for the energy management efficiency measurement indicators, and to calculate the average of the rates of non-achievement of energy management efficiency (the average rate of non-achievement of the energy management efficiency of the data center).

The average calculation unit may output the calculated average in a numerical value form.

Calculating the average may include calculating the average using the following equation:

$$A {V}_{ef}^{N} = \frac{{\sum }_{i = 1}^{N} {( MAX ( \vert {x}_{i} - {UB}_{i} \vert , \vert {x}_{i} - L {B}_{i} \vert ) )}^{2}}{N}$$

where AVef is the average rate of non-achievement of the energy management efficiency of the data center, xi is management efficiency for an i-th energy management efficiency measurement indicator, LBi is a lower limit target value for the i-th energy management efficiency measurement indicator, UBi is an upper limit target value for the i-th energy management efficiency measurement indicator, and N is a number of energy management efficiency measurement indicators of the data center.

xi, LBi and UBi may be each equal to or larger than 0, and may be each equal to or smaller than 1.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a diagram illustrating a conventional method of monitoring the energy management efficiency of a data center using a spider web chart;

FIG. 2 is a diagram illustrating the problem of the conventional method of monitoring the energy management efficiency of a data center using a spider web chart;

FIG. 3 is a diagram illustrating an example of the energy management efficiency of a data center having a plurality of energy management efficiency measurement indicators, which is employed to describe an embodiment of the present invention;

FIG. 4 is a diagram illustrating the configuration of an apparatus for monitoring the energy management efficiency of data center according to an embodiment of the present invention; and

FIG. 5 is a flowchart illustrating a method of monitoring the energy management efficiency of a data center according to an embodiment of the present invention.

### DESCRIPTION OF THE PREFERRED EMBODIMENTS

Embodiments of the present invention will be described in detail below with reference to the accompanying drawings. The same reference numerals are used to designate the same or similar components throughout the drawings. Redundant descriptions of the same components will be omitted.

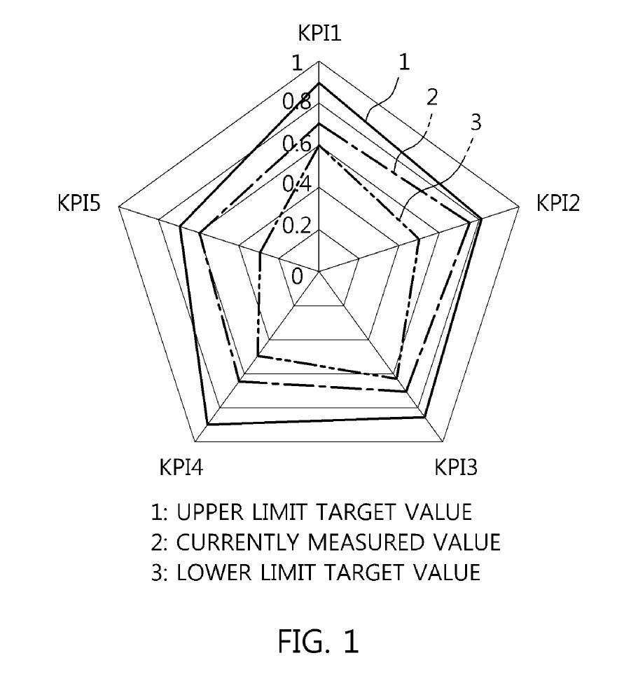

FIG. 1 is a diagram illustrating a conventional method of monitoring the energy management efficiency of a data center using a spider web chart. That is, FIG. 1 illustrates a control chart using a conventional spider web chart that is used to monitor energy management efficiency at a data center.

FIG. 1 illustrates management efficiency on the assumption that a data center has five energy management efficiency measurement indicators. In FIG. 1, Key Performance Indicator (KPI)1 to KPI5 are measurement indicators that are used to measure and evaluate energy management efficiency. Graph 1 illustrates upper limit target values for each of the energy management efficiency measurement indicators in terms of management efficiency, graph 2 illustrates currently measured management efficiency, and graph 3 illustrates energy management efficiency measurement indicator-based lower limit target values in terms of management efficiency.

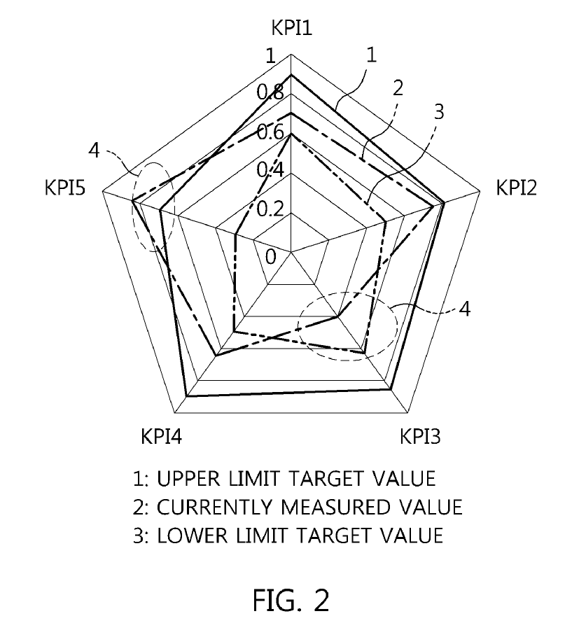

FIG. 2 is a diagram illustrating the problem of the conventional method of monitoring the energy management efficiency of a data center using a spider web chart. That is, FIG. 2 illustrates a problem that occurs when energy management efficiency is monitored by applying the conventional method.

In FIG. 2, the portions 4 surrounded by the dotted lines indicate that currently measured energy management efficiency values deviate from the upper and lower limit target values in terms of management targets.

In this case, the operator of the data center takes necessary measures to enable the values of the corresponding energy management efficiency measurement indicators to fall within the management target values.

It is difficult to perform effective monitoring and control using the conventional method because the corresponding portions do not provide quantitative numerical values.

To overcome the above problem, the present invention discloses a method of quantifying the degree of non-achievement of the energy management efficiency of a data center as described below.

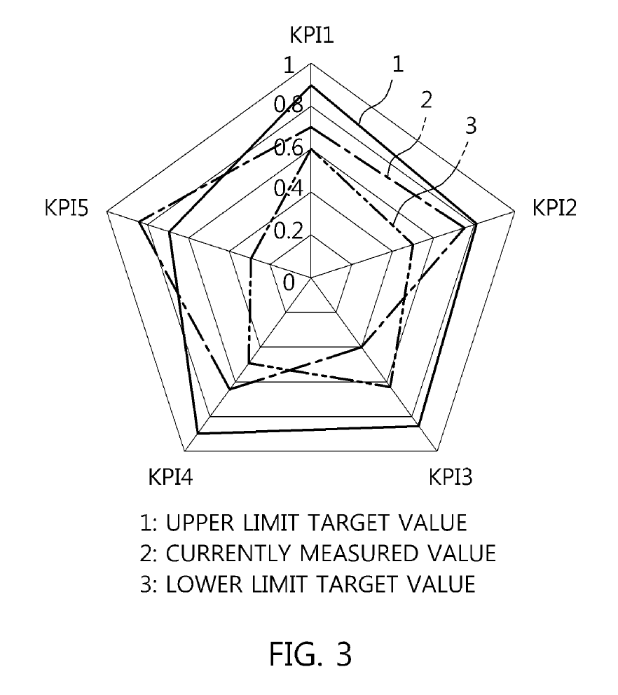

FIG. 3 is a diagram illustrating an example of the energy management efficiency of a data center having a plurality of energy management efficiency measurement indicators, which is employed to describe an embodiment of the present invention.

For example, if it is assumed that the energy management efficiency of the data center is monitored using five energy management efficiency measurement indicators KPI1 to KPI5, the degree of non-achievement of management efficiency may be defined by the following Equation 1:

$$A {V}_{ef}^{5} = \frac{{\sum }_{i = 1}^{5} {( MAX ( \vert {x}_{i} - {UB}_{i} \vert , \vert {x}_{i} - L {B}_{i} \vert ) )}^{2}}{5} \qquad ( 1 )$$

In Equation 1, AV_{ef} is the average rate of non-achievement of the energy management efficiency of the data center, xᵢ is management efficiency for the i-th energy management efficiency measurement indicator (that is, an energy management efficiency measurement indicator value currently measured for the i-th energy management efficiency measurement indicator; 0≦xᵢ≦1), LBᵢ is a lower limit target value for the i-th energy management efficiency measurement indicator (0≦LBᵢ≦1), and UBᵢ is an upper limit target value for the i-th energy management efficiency measurement indicator (0≦UBᵢ≦1).

When the above-described qualification method is applied to the case of FIG. 3, the average rate of non-achievement of energy management efficiency is calculated as follows:

TABLE 1

| | KPI1 | KPI2 | KPI3 | KPI4 | KPI5 |
|---|---|---|---|---|---|
| Upper limit target value | 0.9 | 0.8 | 0.85 | 0.9 | 0.7 |
| Measured value | 0.7 | 0.7 | 0.4 | 0.65 | 0.85 |
| Lower limit target value | 0.6 | 0.5 | 0.63 | 0.5 | 0.3 |

When the measured values entered in Table 1 are applied to Equation 1, the average rate of non-achievement of the energy management efficiency of the data center may be calculated as 6.75%.

Accordingly, the average rate of non-achievement of the energy management efficiency of a data center having N energy management efficiency measurement indicators may be calculated by the following Equation 2 obtained by extending Equation 1:

$$A {V}_{ef}^{N} = \frac{{\sum }_{i = 1}^{N} {( MAX ( \vert {x}_{i} - {UB}_{i} \vert , \vert {x}_{i} - L {B}_{i} \vert ) )}^{2}}{N} \qquad ( 2 )$$

In Equation 2, AV_{ef} is the average rate of non-achievement of the energy management efficiency of the data center, xᵢ is management efficiency for the i-th energy management efficiency measurement indicator (that is, a management efficiency measurement indicator value currently measured for the i-th energy management efficiency measurement indicator), LBᵢ is a lower limit target value for the i-th energy management efficiency measurement indicator, UBᵢ is an upper limit target value for the i-th energy management efficiency measurement indicator, and N is the number of energy management efficiency measurement indicators of the data center.

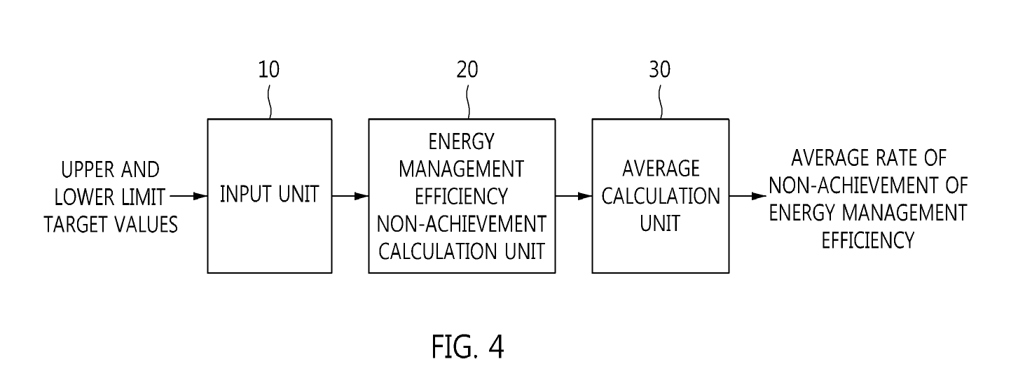

FIG. 4 is a diagram illustrating the configuration of an apparatus for monitoring the energy management efficiency of data center according to an embodiment of the present invention.

The apparatus for monitoring the energy management efficiency of data center according to this embodiment of the present invention includes an input unit 10, an energy management efficiency non-achievement calculation unit 20, and an average calculation unit 30.

The input unit 10 receives upper and lower limit target values for each of the energy management efficiency measurement indicators. In this case, the energy management efficiency measurement indicators may be the five indicators KPI1 to KPI5 illustrated above. The upper and lower limit target values for each of the energy management efficiency measurement indicators may be input by a user (an administrator or an operator).

The energy management efficiency non-achievement calculation unit 20 calculates the rate of non-achievement of energy management efficiency for each of the energy management efficiency measurement indicators based on values currently measured for each of the energy management efficiency measurement indicators (e.g., KPI1 to KPI5) and the upper and lower limit target values received from the input unit 10.

The average calculation unit 30 receives the rates of non-achievement of energy management efficiency for the energy management efficiency measurement indicators from the energy management efficiency non-achievement calculation unit 20. Thereafter, the average calculation unit 30 calculates the average of the rates of non-achievement of energy management efficiency (i.e., the average rate of non-achievement of energy management efficiency).

The average calculation unit 30 may output the calculated average rate of non-achievement of energy management efficiency in the form of a numerical value. The reason why the average calculation unit 30 outputs the average rate of non-achievement of energy management efficiency in the form of a numerical value is to enable the operator to be aware of current energy management efficiency in a quantitative form. This enables the operator to easily determine whether the current energy management efficiency falls within a range of the target values.

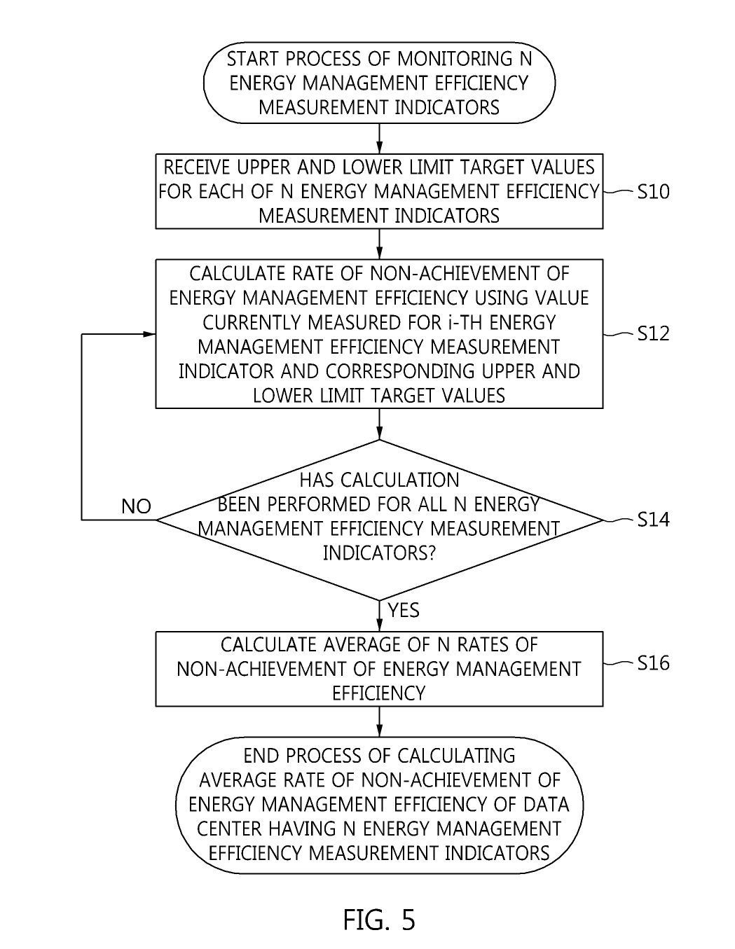

FIG. 5 is a flowchart illustrating a method of monitoring the energy management efficiency of a data center according to an embodiment of the present invention.

When monitoring based on N energy management efficiency measurement indicators (e.g., KPI1 to KPI5) starts, the input unit 10 receives upper and lower limit target values for each of the N energy management efficiency measurement indicators at step S10. In this case, the upper and lower limit target values for the N energy management efficiency measurement indicators may be the values illustrated in the above-described Table 1.

Thereafter, the energy management efficiency non-achievement calculation unit 20 receives an energy management efficiency measurement indicator value currently measured for the i-th management efficiency measurement indicator, and also receives upper and lower limit target values for the N energy management efficiency measurement indicators from the input unit 10. In this case, the energy management efficiency measurement indicator value currently measured for the i-th management efficiency measurement indicator is a value that is measured by the user (administrator). The energy management efficiency non-achievement calculation unit 20 calculates the rate of non-achievement of energy management efficiency for each of the energy management efficiency measurement indicators based on the energy management efficiency measurement indicator value currently measured for each of the energy management efficiency measurement indicators and the upper and lower limit target values for each of the energy management efficiency measurement indicators at step S12. The rate of non-achievement of energy management efficiency for each of the energy management efficiency measurement indicators calculated by the energy management efficiency non-achievement calculation unit 20 is transferred to the average calculation unit 30.

If the rates of non-achievement of energy management efficiency have been calculated for all the energy management efficiency measurement indicators up to the N-th energy management efficiency measurement indicator (“YES” at step S14), the average calculation unit 30 calculates the average of the N rates of non-achievement of energy management efficiency (that is, the average rate of non-achievement of energy management efficiency) at step S16. In this case, the average calculation unit 30 may calculate the average rate of non-achievement of energy management efficiency based on the above-described Equation 2. Furthermore, the average calculation unit 30 may output the calculated average rate of non-achievement of energy management efficiency.

Through the output of the calculated average rate of non-achievement of energy management efficiency, the process of calculating the average rate of non-achievement of the energy management efficiency of the data center having N energy management efficiency measurement indicators is terminated.

In accordance with the present invention configured as described above, currently measured management efficiency values are indicated on a chart on which upper and lower limit target values for management efficiency have been indicated using a control chart, such as a spider web chart, thereby providing information that enables energy management efficiency to be quantitatively determined. This enables an operator to easily determine whether current energy management efficiency falls within a set range of target values.

Furthermore, the present invention may be used in a method capable of monitoring management efficiency in a data center having a plurality of independent energy management efficiency indicators in real time.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A method of monitoring energy management efficiency of a data center, comprising:
receiving, by an input unit, upper and lower limit target values for each of energy management efficiency measurement indicators;
calculating, by an energy management efficiency non-achievement rate calculation unit, a rate of non-achievement of energy management efficiency for each of the energy management efficiency measurement indicators based on an energy management efficiency measurement indicator value currently measured for each of the energy management efficiency measurement indicators and the upper and lower limit target values; and
receiving, by an average calculation unit, the rates of non-achievement of energy management efficiency for the energy management efficiency measurement indicators, and calculating, by the average calculation unit, an average of the rates of non-achievement of energy management efficiency.

2. The method of claim 1, wherein calculating the average comprises outputting the calculated average in a numerical value form.

3. The method of claim 1, wherein calculating the average comprises calculating the average using the following equation:
$$A {V}_{ef}^{N} = \frac{{\sum }_{i = 1}^{N} {( MAX ( \vert {x}_{i} - {UB}_{i} \vert , \vert {x}_{i} - L {B}_{i} \vert ) )}^{2}}{N}$$
where AV_{ef} is the average rate of non-achievement of the energy management efficiency of the data center, xᵢ is management efficiency for the i-th energy management efficiency measurement indicator, LBᵢ is a lower limit target value for the i-th energy management efficiency measurement indicator, UBᵢ is an upper limit target value for the i-th energy management efficiency measurement indicator, and N is a number of energy management efficiency measurement indicators of the data center.

4. The method of claim 3, wherein xᵢ, LBᵢ and UBᵢ are each equal to or larger than 0, and are each equal to or smaller than 1.

5. An apparatus for monitoring energy management efficiency of a data center, comprising:
an input unit configured to receive upper and lower limit target values for each of energy management efficiency measurement indicators;
an energy management efficiency non-achievement rate calculation unit configured to calculate a rate of non-achievement of energy management efficiency for each of the energy management efficiency measurement indicators based on an energy management efficiency measurement indicator value currently measured for each of the energy management efficiency measurement indicators and the upper and lower limit target values; and
an average calculation unit configured to receive the rates of non-achievement of energy management efficiency for the energy management efficiency measurement indicators, and to calculate an average of the rates of non-achievement of energy management efficiency.

6. The apparatus of claim 5, wherein the average calculation unit outputs the calculated average in a numerical value form.

7. The apparatus of claim 5, wherein calculating the average comprises calculating the average using the following equation:
$$A {V}_{ef}^{N} = \frac{{\sum }_{i = 1}^{N} {( MAX ( \vert {x}_{i} - {UB}_{i} \vert , \vert {x}_{i} - L {B}_{i} \vert ) )}^{2}}{N}$$
where AV_{ef} is the average rate of non-achievement of the energy management efficiency of the data center, xᵢ is management efficiency for an i-th energy management efficiency measurement indicator, LBᵢ is a lower limit target value for the i-th energy management efficiency measurement indicator, UBᵢ is an upper limit target value for the i-th energy management efficiency measurement indicator, and N is a number of energy management efficiency measurement indicators of the data center.

8. The apparatus of claim 7, wherein xᵢ, LBᵢ and UBᵢ are each equal to or larger than 0, and are each equal to or smaller than 1.
